(19) United States
(12) Patent Application Publication
(10) Pub. No.: US 2009/0045320 A1
(43) Pub. Date: Feb. 19, 2009

(54) Method, apparatus and system for a low power imager device

(76) Inventor: Chen Xu, Boise, ID (US)

Correspondence Address: DICKSTEIN SHAPIRO LLP, 1825 EYE STREET NW, Washington, DC, 20006-5403, US

(21) Appl. No.: 11/889,694

(22) Filed: Aug. 15, 2007

(51) Int. Cl. H01L 27/00

(52) U.S. Cl. 250/208.1; 250/214 R

(57) ABSTRACT

A method, apparatus and system providing an imaging device in which a bias current supplied to one or more imaging device circuits is adjusted in accordance with a frequency of a pixel clock signal.

### FIELD OF THE INVENTION

Embodiments relate to a method, apparatus and system for a lower power imager device.

### BACKGROUND

An imaging device 10 (FIG. 1) typically includes a plurality of pixels, each having an associated photosensor, arranged in an array 20. A column parallel readout may be employed to sample the signals generated by the pixels. In a column parallel readout, a column switch associated with a column driver 60 and associated column address decoder 70 for each column of the array selectively couples a column output line to a readout circuit while a row of the array is selected for readout by row address decoder 40 and row driver 30.

For a CMOS imaging device employing so-called active pixel sensors, a DC bias source 62 (FIG. 1A) is typically associated with each column line 64 of array 20, to which column pixels associated with the column line can be connected. The DC bias source 62 generates and provides a bias current to pixels selectively connected to the column line 64 during readout. A control circuit 50 typically controls operation of the pixels of the array 20 for image charge integration and signal readout of pixel array 20. Each pixel normally includes a source-follower transistor that provides a reset Vrst output signal and photogenerated Vsig voltage output signal. The bias current generated and provided by the DC bias source 62 enables a source-follower transistor within each pixel to provide an output voltage to the column output line 64 for the column to which that pixel belongs.

In addition, as further shown in FIG. 1, the readout circuit employs an analog processing chain which processes read out pixel signals. The analog processing chain typically includes a sample and hold circuit 72 for sampling and holding the reset Vrst and photogenerated output signal Vsig and a differential amplifier 74 for subtracting the Vrst and Vsig signals to generate a pixel output signal. These circuits also require a DC bias from a DC bias source. The readout circuit also includes an analog-to-digital converter 77, which receives the analog pixel output signal and digitizes it. The converter 77 also receives a DC bias from a DC bias source to set a reference voltage used by converter 77. The output of the analog-to-digital converter is supplied to an image processor 110.

The digital imaging industry is trending towards higher resolution arrays (i.e., more pixels) simultaneous with faster readout speeds and higher frame rates. In order to meet the high resolution/fast frame rate demands, imaging devices are currently being designed to sustain a worst case power-use scenario of full resolution at maximum pixel clock frequency. The DC bias current sources 62 for the column lines 64, the analog signal processing circuits, e.g. 72, 74 and the analog-to-digital converter 77 are accordingly set to supply a high current level needed for the highest resolution and fastest frame rate to ensure that enough power is available for the most power intensive operations. Other modes of operation, however, may not require full power in order to function. High power use for prolonged periods of time generates a great deal of heat and causes unnecessary power drain.

### BRIEF DESCRIPTION OF THE DRAWINGS

FIG. 1 is a simplified block diagram of an imaging device.

FIG. 1A is a schematic diagram of a simplified column biasing circuit.

FIG. 2 is a graph showing curves plotting the relationship between pixel clock frequency (pixclk) and analog buffer bias current (I_{D}).

FIG. 3 is a block diagram of an imaging device employing an embodiment of the invention.

FIG. 4 shows details of a typical analog signal processing circuit shown in FIG. 3.

FIG. 4A is a schematic diagram of a simplified column line biasing circuit which may be used in the FIG. 3 imaging device.

FIG. 5 is a flowchart illustrating an embodiment of a method of operating an imaging device shown in FIG. 3.

FIG. 6 is a processor system incorporating at least one imaging device constructed in accordance with an embodiment employing the FIG. 3 imaging device.

### DETAILED DESCRIPTION OF THE INVENTION

In the following detailed description, reference is made to the accompanying drawings which form a part hereof, and which illustrate specific embodiments. These embodiments are described in sufficient detail to enable those of ordinary skill in the art to make and use them. It is also understood that structural, logical, or procedural changes may be made to the specific embodiments disclosed herein.

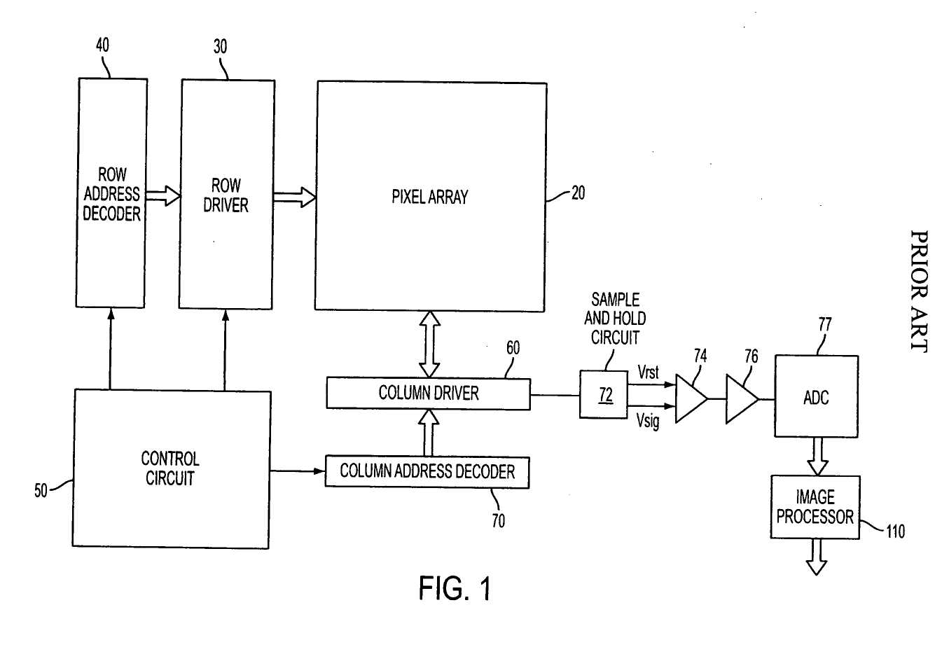

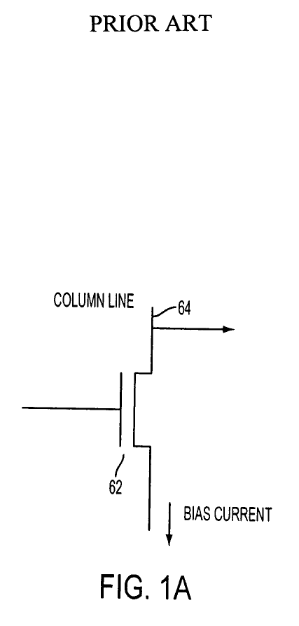

The bandwidth of the analog signal processing chain of an imaging device formed, for example, by a column readout circuit 62 and analog circuits 72, 74, 77 (FIG. 1), is related to the speed of analog signal processing through the chain. The analog signal processing chain bandwidth may be approximated by the following simplified equation:

$$BW = \frac{{g}_{m}}{C} = \sqrt{\frac{2 {I}_{D} {μ}_{n} {C}_{ox} ( W / L )}{C}} \qquad ( 1 )$$

which represents the bandwidth of an analog operational amplifier provided in the processing chain, where BW denotes the bandwidth, gₘ denotes a transconductance of a transistor in the operational amplifier, Cₒₓ denotes the capacitative load seen at the output, C denotes the capacitative load seen by the output stage, μₙ denotes the channel mobility of the transistor, I_{D} denotes the bias current supplied to the analog signal processing chain, and W and L are the width and length of the output transistor, respectively. As can be seen, under equal loads the bandwidth BW is proportional to the square root of the bias current I_{D}. It should also be understood that differential amplifiers, analog-to-digital converters and other analog processing circuits may comprise many stages of operational amplifiers where power is consumed.

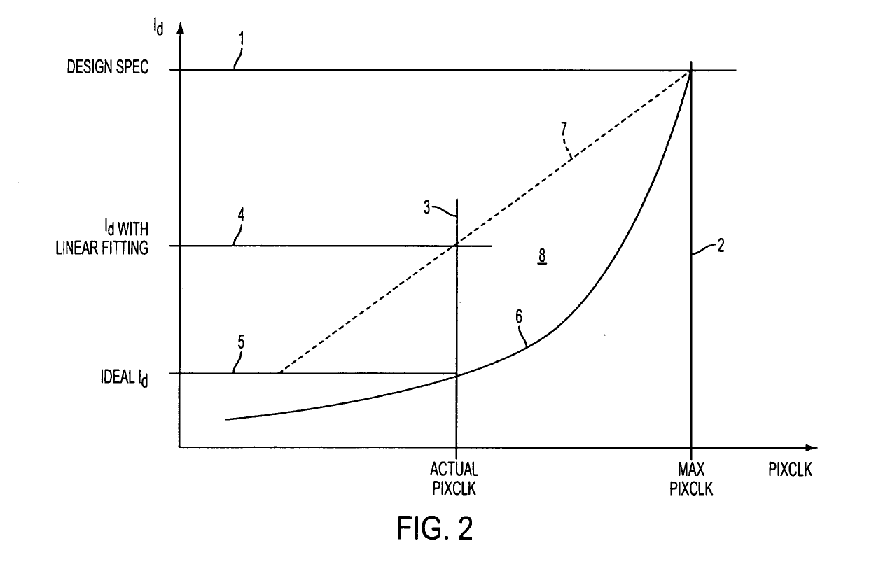

FIG. 2 shows a graph of the pixel clock frequency (Pixclk) versus analog signal processing chain bias current (I_{D}). The bandwidth is largely determined by the pixel clock frequency, which varies according to the frame rate of a given mode of imaging device operation. As the pixel clock frequency increases or decreases, the bandwidth proportionally follows. Hereinafter, for simplicity, the bandwidth BW in equation (1) will be viewed as directly related to pixel clock frequency.

A conventional imaging device 10 is designed to maintain a bias current level required to support a maximum pixel clock frequency (Max pixclk), as illustrated on the graph by line 1, labeled “Design spec.” If an imaging device 10 is being operated in a mode having a pixel clock frequency (Pixclk) lower than the maximum pixel clock frequency, for example, a low frame rate or resolution mode represented by line 3, labeled “Actual pixclk,” the conventional design specification still applies the bias current level necessary to support the maximum pixel clock frequency, (i.e., at a location of line 2). Equation (1) shows that the actual required bias current I_{D} drops as the bandwidth BW (and correspondingly, the pixel clock frequency) decreases, indicated by curve 6 on the graph of FIG. 2. Curve 6 represents an ideal operational relationship between pixel clock frequency and the analog blocks bias current I_{D}. Thus, in a low frame rate mode of operation, an unnecessarily high bias level is conventionally maintained at the analog signal processing circuits although the ideal bias current level according to equation (2) is much lower, shown by line 5, labeled “Ideal I_{D}.”

The proportional square root relationship between bandwidth BW and bias current I_{D} expressed in equation (1) and illustrated by curve 6 is only valid under ideal conditions that ignore practical disrupting factors. For example, all transistors are assumed to be ideally biased at the saturation region, which is not often the case. Other mitigating factors, such as temperature and short channel effects (channel length modulation, drain induced barrier lowering, etc.), may also offset the actual required bias current value for a given pixel clock frequency. Due to such offsets, equation (1) may not accurately portray the relationship of pixel clock frequency and bias current I_{D}.

Accordingly, equation (2) below may be used to determine a more practical relationship between the bias current I_{D} and pixel clock frequency:

$${I}_{bias} = \frac{{I}_{bias\_max} \cdot Pixclk}{{Pixclk}_{max}} = α \cdot Pixclk \qquad ( 2 )$$

Equation (2), which is represented by dashed line 7 in FIG. 2, expresses a linear relationship that reduces the bias current I_{bias} proportionally with a reduction of the pixel clock frequency. Using equation 2, an imaging device can determine an appropriate reduced bias current I_{bias} for one or more circuits in the analog signal processing chain whenever there is a change in pixel clock frequency. Thus, when the pixel clock increases, a higher bias current I_{bias} value may be determined and set. Likewise, when the pixel clock decreases, a lower bias current I_{bias} value may be determined and set.

Reducing the bias current I_{bias} after a decrease in the pixel clock signal frequency will result in a reduction of analog power consumption in a circuit in the analog signal processing chain (i.e., Power_{buffer}=Vaa×I_{bias}). The reduction in power can be significant, especially when in a mode of operation of an imaging device having a particularly low pixel clock frequency, e.g., when an imaging device is operated in a VGA preview mode.

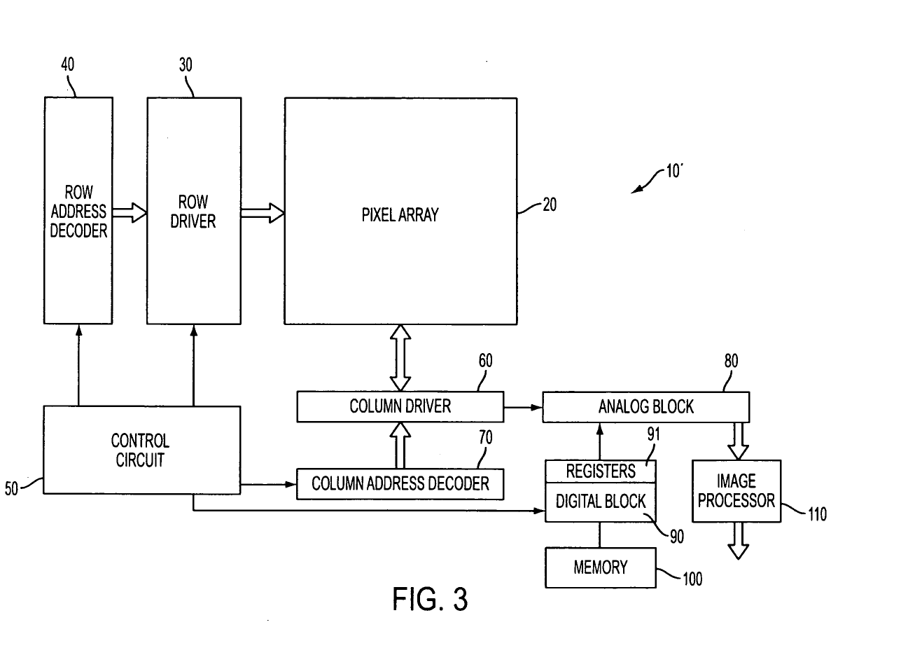

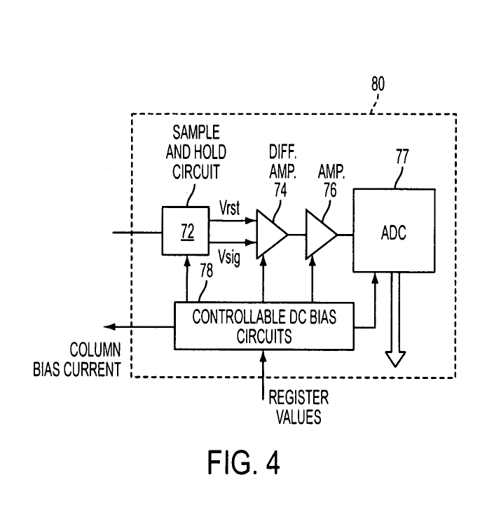

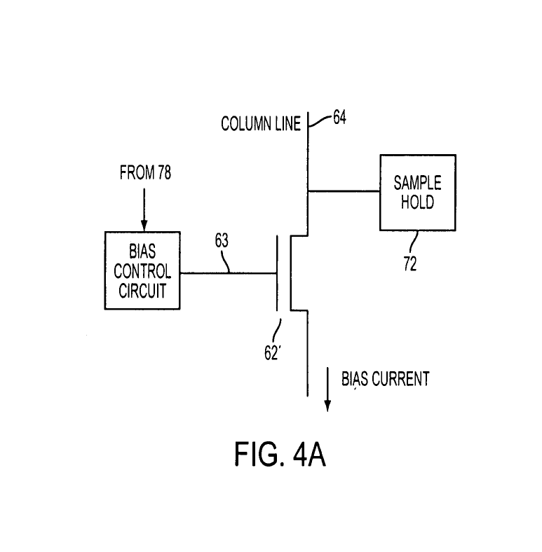

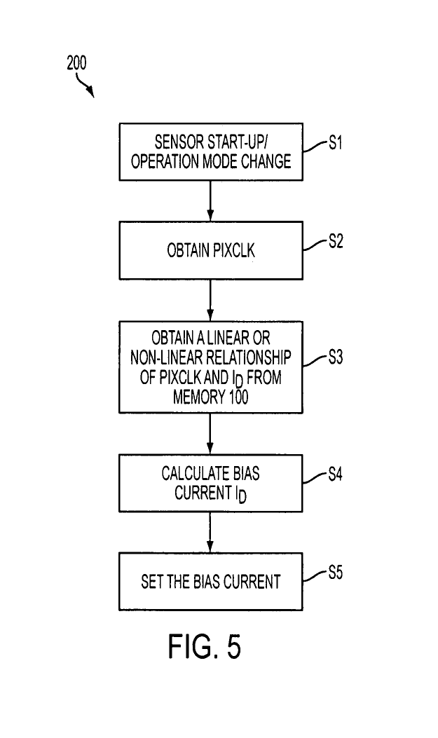

FIGS. 3, 4, and 5 illustrate embodiments of apparatuses, methods and systems which may be employed as non-limiting examples of achieving power reduction in an imaging device according to the principles explained above. FIG. 3 shows a block diagram of an embodiment of an imaging device 10′. FIG. 4 illustrates details of an exemplary analog block 80 shown in FIG. 3. FIG. 4A illustrates a column line biasing circuit which may be used in FIG. 3. FIG. 5 illustrates an operating method of imaging device 10′.

Referring now to FIGS. 3 and 4, the imaging device 10′ has analog signal processing circuits in the analog signal processing block 80, one or more of which can operate with one or more adjustable bias currents. It should be understood that analog signal processing block 80 is only one example of an analog block in imaging device 10′ and other analog blocks, such as the analog buffer of the analog voltage references may benefit from bias current adjustment as described herein. Analog circuits within analog block 80 having one or more adjustable bias currents may include one or more of an analog-to-digital converter 77 (FIG. 4) and an analog signal processing chain, including sample-and-hold circuit 72, differential amplifier 74 and one or more gain amplifiers 76. The analog-to-digital converter 77, for example, utilizes a bias current to set a reference voltage for converter operation. The imaging device 10′ may also employ a column line biasing circuit 62′ (FIG. 4A), which may also have a signal line 63 for setting an adjustable bias level applied to the column line 64. The imaging device 10′ further includes a pixel array 20, row and column address decoders 40, 70, row and column drivers 30, 60, and control circuit 50, all operating as described above with reference to FIG. 1. Analog block 80 may include a controllable DC bias circuit 78 for setting the levels of one or more bias currents from values set in registers respectively corresponding to each of the bias currents supplied to each of the circuits within analog block 80 and the column line bias circuit 62′.

The analog signal processing chain illustrated as part of analog block 80 in FIG. 4 is merely one example of the circuits which may be contained within analog block 80. Moreover, not all analog circuits within analog block 80 need have their respective bias circuits adjusted in accordance with pixel clock frequency. As noted, embodiments described herein may be used to adjust one or more bias currents in one or more of the column line bias circuits 62′, sample and hold circuit 72, differential amplifier 74, one or more gain amplifiers 76, and analog-to-digital converter 77.

Referring back to FIG. 3, a memory device 100 is included and electrically connected to a digital block 90. Memory device 100 operates to determine a level for the various bias currents used in the analog block 80 circuits and column line bias circuit 67′ and sets registers 91 respectively associated with each bias current or values. The digital block 90 is electrically connected to control circuit 50 and to the controllable bias circuit 78 through registers 91. Digital block 90 receives a signal from control circuit 50 representing the current pixel clock signal frequency used in operating the pixel array. Digital block 90 uses this information to determine the bias current which is to be applied by controllable bias circuit 78 to the adjustable bias circuits within the analog block 80 and to the column line bias circuit 62′ and sets a corresponding value in a respective register 91. After determining what the respective bias current should be for a given analog circuit, the digital block 90 sends an appropriate signal to the register 91 associated with a bias circuit of a particular analog circuit to set the bias current. The register value is read by the controllable bias circuit 78 to set a bias current.

Bias currents may be set by the controllable bias circuit 78, which sets a bias level in accordance with register values already typically present in an imager device. No hardware changes or additions are required to the conventional imaging device analog block 80 other than providing digital block 90 and associated memory 100 for setting values in the registers in accordance with a determined pixel clock frequency.

Power reduction by adjusting bias currents based on pixel clock frequency may ultimately be realized in an imaging device 10′ in several ways. Referring to equation (2), an expression of the relationship between the pixel clock signal frequency Pixclk and the bias current I_{bias} level (set in registers 91) used to operate circuits within the analog block 80 may be stored in memory device 100. A memory device 100 such as a read-only memory (ROM) would be suitable for this purpose. Using equation (2) to define the relationship, the stored information may be a register setting per se in a look-up table, or may comprise a parameter α, which is a multiplier of the pixel clock signal frequency Pixclk. A more complicated relationship other than a linear or square relationship as shown above may also be stored, such as a customized polynomial relationship between Pixclk and I_{bias}. Information comprising an initital setting for each bias current could also be stored in the memory device 100 for a default operational mode, for example, for initial use after start-up.

Whenever there is a change in the pixel clock frequency, e.g., upon a change in operational mode, a new bias current level I_{bias} can be determined for one or more bias currents for one or more of the analog circuits within analog block 80 or the column line bias circuit 62′ by digital block 90 according to equation (2), or by looking up a new register value associated with the new pixel clock frequency. After digital block 90 determines from Pixclk a corresponding current bias level I_{bias}, the adjustment may be performed by writing a value in register 91. Controllable DC bias source 78 uses the value in register 91 to set a bias current level to one or more of the analog circuits within the analog block 80 or to the column line bias circuit 62′.

The digital block 90 can adjust the present bias current level as described above automatically or on an as-needed basis. For example, the digital block 90 may store a power-saving threshold value and only adjust bias current levels if a power reduction associated with a new bias current exceeds the threshold value. This would prevent minute adjustments in bias current that would have no practical benefit.

Equation (2) shows one linear relationship between pixel clock frequency and an operational amplifier bias current I_{bias} as one example. However, other linear and non-linear relationships may be employed to better match a bias current I_{bias} of a particular analog circuit to pixel clock frequency Pixclk. Indeed, at least any relationship of the two which produces a curve falling in region 8 between line 7 and curve 6 of FIG. 2 could potentially be used to provide improved power reduction. In addition, there may be different relationships stored for different bias currents used by the circuits whose bias current level is adjusted in accordance with pixel clock frequency. Furthermore, while memory device 100 can be a ROM, this is only one example of a memory device which can be used. For example, memory device 100 could be constructed as a bank of laser fuses or one-time programmable memory elements or other storage devices. A look-up table may be advantageously stored in memory device 100 to store a linear or more precise, non-linear relationship between pixel clock frequency and bias current I_{bias} for use by digital block 90.

Also, it should be understood that a circuit which has a bias current level which is adjustable in accordance with pixel clock frequency may have more than one bias current which is adjustable in accordance with pixel clock frequency in accordance with the embodiments described herein.

FIG. 5 shows a flowchart of one method 200 of operating an imaging device 10′ to adjust a bias current I_{bias} for one or more analog circuits within analog block 80. At step S1, the pixel clock frequency of the imaging device 10′ is changed, for example, by a start-up of the imaging device 10′ or an operational mode change. A value for the set pixel clock frequency (pixclk) is obtained from the control circuit 50, for example, from phase-locked loop (pll) registers within the control circuit 50 and an external clock signal (ext_clk) at step S2. Next, at step S3 the information expressing the relationship between pixel clock frequency (pixclk) and the bias current level (e.g., a parameter α, or a look-up table of register values) is obtained from the memory 100. The pixel clock frequency (pixclk) information and the relationship information are used to determine one or more bias current levels in digital block 90 (FIG. 3) at step S4 for one or more analog circuits within analog block 80 and/or for column line biasing circuit 62′. The levels are set as digital values in control registers 91 which set the bias current supplied by the controllable DC bias 78 in step S5.

Although embodiments have been described in which analog signal processing circuits, including one or more of the column line bias circuit, sample-and-hold circuit 72, differential amplifier 74, one or more amplifiers 76, or analog-to-digital converter 77 in the analog signal processing chain have one or more bias currents adjusted in accordance with pixel clock frequency, the bias current of other operable circuits within an imaging device 10′ may also be likewise adjusted.

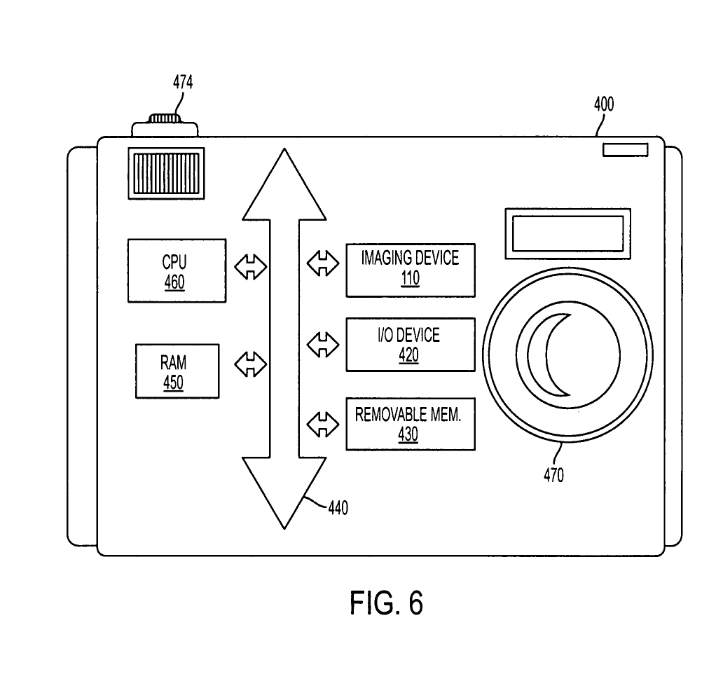

FIG. 6 shows an image processor system 400, for example, a still or video digital camera system, which includes an imaging device 10′ constructed in accordance with an embodiment. The imaging device 10′ may receive control or other data from system 400. The imaging device 10′ receives light on pixel array 20 thru the lens 470 when shutter release button 474 is pressed. System 400 includes a control processor 460 having a central processing unit (CPU) that controls operations of the system and communicates with various devices over one or more buses or bridges 440. Some of the devices connected to the buses and/or bridges 440 provide communication into and out of the system 400; one or more input/output (I/O) devices 420, e.g., input setting devices, LCD display, and imaging device 10′ are such devices. Other devices connected to the buses and/or bridges 440 provide memory, illustratively including a random access memory (RAM) 450, and one or more peripheral memory devices such as a removable memory 430. The imaging device 10′ may be coupled to processor 460 for receiving control commands and providing image data. In addition to a still or video camera, examples of other processor based systems which may employ imaging device 10′ include, without limitation, computer systems, scanners, machine vision systems, vehicle navigation systems, video telephones, surveillance systems, auto focus systems, star tracker systems, motion detection systems, and others.

While embodiments have been described in detail, it should be readily understood that the invention is not limited to the disclosed embodiments. Rather the embodiments can be modified to incorporate any number of variations, alterations, substitutions or equivalent arrangements not heretofore described. Accordingly, the invention is not limited by the foregoing description but is only limited by the scope of the attached claims.

1. A method of operating an imaging device having a pixel array, comprising:
storing a relationship between a pixel clock signal frequency and a bias current level in a memory;
obtaining a pixel clock signal;
determining a bias current level of a circuit of said imaging device according to the relationship between the pixel clock signal frequency and the bias current level; and
setting a bias current level of said circuit according to the determined level.

2. The method of claim 1, wherein the bias current is a bias current of an analog signal amplifier circuit of said imaging device.

3. The method of claim 1, wherein the bias current is a bias current of a sample-and hold circuit of said imaging device.

4. (canceled)

5. The method of claim 1, wherein the bias current is a bias current of a differential amplifier circuit of said imaging device.

6. The method of claim 1, wherein the bias current is a bias current of an analog-to-digital converter circuit of said imaging device.

7. The method of claim 1, wherein the relationship is a non-linear relationship.

8. The method of claim 1, wherein the relationship is a linear relationship.

9. The method of claim 1, wherein the relationship is stored as a look-up table.

10. The method of claim 1, wherein the relationship is stored as a parameter of an equation for determining a bias current level.

11. (canceled)

12. (canceled)

13. The method of claim 1, wherein the relationship is stored as a coefficient for multiplying with a value representing a pixel clock frequency.

14. The method of claim 1, wherein said setting step is preferred only when a determined bias level exceeds a threshold for changing a bias current level.

15. A method of operating an imaging device, comprising:
storing a relationship between a pixel clock signal frequency and a bias current level in a memory;
obtaining first information representing a frequency of a pixel clock signal;
obtaining second information representing the relationship between the pixel clock signal frequency and at least one bias current level of at least one analog circuit;
using the first and second information to determine a level for the at least one bias current; and
using the determined level to set the at least one bias current level for the at least one analog circuit.

16. The method of claim 15, wherein the second information corresponds to a parameter stored in a memory associated with the imaging device.

17. The method of claim 15, wherein the second information is obtained by reading a value from a look-up table stored in a memory device associated with the imaging device.

18. (canceled)

19. (canceled)

20. The method of claim 15, wherein:
the second information obtained represents a relationship between the pixel clock signal frequency and at least one bias current of each of a plurality of analog circuits;
the first and second information are used to determine at least one bias current level for each of said plurality of analog circuits; and
the determined bias current levels are used to set at least one bias current for each of said plurality of analog circuits.

21. A method of operating an imaging device, comprising:
storing, in a memory, first information expressing a relationship between at least one bias current of a first pixel signal circuit and a pixel clock signal frequency;
determining upon a change in the pixel clock signal frequency, a new circuit bias current level for said at least one bias circuit of said first pixel signal circuit according to the stored first information and a pixel clock signal frequency; and
supplying the new bias current level to the first pixel signal circuit.

22. The method of claim 21, further comprising:
determining a startup bias current level for said first pixel signal analog circuit; and
presetting the imaging device to operate at the startup circuit bias current level for said first pixel signal circuit upon startup of the imaging device.

23. The method of claim 21, further comprising:
obtaining second information expressing a relationship between at least one bias circuit of a second pixel signal circuit and said pixel clock signal frequency;
determining upon a change in pixel clock frequency a new circuit bias current level for said second pixel signal circuit according to said obtained second information; and
supplying the new bias current level to the second pixel signal circuit.

24. An imaging device, comprising:
a pixel array;
at least one circuit associated with processing a pixel signal from said array, the at least one circuit having an associated bias current;
a clock circuit for generating a pixel clock signal having a given frequency;
a memory device for storing information representing a relationship between a level of bias current and a frequency of said pixel clock signal: and
a circuit for setting a level of said bias current in accordance with a frequency of said pixel clock signal based on said stored information.

25. The imaging device as in claim 24, further comprising a plurality of analog circuits for processing said pixel signal, said setting circuit setting a level of a bias current in a plurality of said analog circuits in accordance with a frequency of said pixel clock signal.

26. (canceled)

27. The imaging device of claim 26, wherein said information represents a linear relationship between a level of bias current and a frequency of said pixel clock signal.

28. The imaging device of claim 26, wherein said information represents a non-linear relationship between a level of bias current and a frequency of said pixel clock signal.

29. (canceled)

30. (canceled)

31. (canceled)

32. (canceled)

33. (canceled)

34. An imaging device comprising:
a pixel array containing a plurality of pixel column lines;
a bias circuit connected to a respective pixel column line;
a memory device for storing information representing a relationship between a level of bias current and a frequency of said pixel clock signal;
a sequence of analog circuits for receiving and processing pixel signals from said respective column line; and
a circuit for changing a bias current level of at least one of said bias circuit and an analog circuit in said sequence in accordance with changes in a pixel clock signal frequency based on said stored information.

35. (canceled)

36. The imaging device of claim 34 wherein said image processing system is a camera system.
